(19) United States
(12) Patent Application Publication
(10) Pub. No.: US 2024/0404973 A1
(43) Pub. Date: Dec. 5, 2024

(54) WAFER LEVEL PROCESS FOR SEMICONDUCTOR DEVICE PACKAGE

(71) Applicant: Texas Instruments Incorporated, Dallas, TX (US)

(72) Inventors: Mohamad Ashraf bin Mohd Arshad, Kuala Lumpur (MY); Jeffrey Salvacion Solas, Angeles City (PH); Ruby Ann Merto Camenforte, Pampanga (PH); Huay Yann Tay, Melaka (MY); Chia Wei Chang, New Taipei City (TW); Xiaolei Liao, Chengdu (CN)

(21) Appl. No.: 18/327,036

(22) Filed: May 31, 2023

(51) Int. Cl. H01L 23/00; H01L 21/56

(52) U.S. Cl. CPC H01L 24/19; H01L 21/561; H01L 21/565; H01L 21/568; H01L 24/20; H01L 2224/19; H01L 2224/2101; H01L 2224/2105; H01L 2224/211; H01L 2224/214; H01L 2224/215; H01L 2924/182

(57) ABSTRACT

An example semiconductor device package includes a semiconductor die having bond pads on a device side surface, and a build-up routing layer on the semiconductor die including: connection level conductors directly contacting the bond pads; trace level conductors on the connection level conductors directly contacting distal ends of the connection level conductors; dielectric material surrounding the connection level conductors and the trace level conductors; terminals formed of portions of a top layer of the trace level conductors having a board side surface exposed from the dielectric material, wherein an electrical connection between the terminals and the bond pads is formed without a solder joint or a bond wire; and mold compound covering a portion of the semiconductor die, the trace level conductors and the connection level conductors of the build-up routing layer, wherein the board side surface of the terminals is exposed from the mold compound.

### TECHNICAL FIELD

This disclosure relates generally to semiconductor device packages, and more particularly to semiconductor device packages including one or more semiconductor dies coupled to terminals of the package by conductors formed in a wafer level process.

### BACKGROUND

Processes for producing semiconductor device packages include mounting a semiconductor die to a package substrate, and covering the electronic devices with a dielectric material such as a mold compound to form packaged devices. In a popular approach, a lead frame with conductive leads is used to mount a semiconductor die in a flip chip die mount. When a flip chip die is mounted to a lead frame, the process can be referred to as “flip chip on lead” or “FCOL.” Flip chip mounted semiconductor dies feature conductive post connects extending from the bond pads on a device side surface of the semiconductor dies. The conductive post connects end in a solder ball or bump. The conductive post connects can be made of copper, and can be shaped as a column or pillar, the copper post connects are sometimes referred to as “copper pillars” or “copper pillar bumps” when the solder is included. The semiconductor die is mounted on a lead frame in a FCOL process by positioning the solder to contact conductive leads of the lead frame, and performing solder reflow to mechanically connect the conductive post connects to the leads of the lead frame. The lead frame provides signal routing and portions of the leads form terminals for the semiconductor device package.

A molding process then covers the semiconductor die, the conductive post connects and portions of the package substrate, for example the lead frame described above, with mold compound. Portions of the leads that form terminals are exposed from the mold compound for mounting the semiconductor device package to a system board. Increasingly “no-lead” packages are used, where the terminals are coextensive with the mold compound, and the bottom surface of the terminals is exposed from the mold compound and used for surface mounting the semiconductor device package. In some examples, the leads have flanks or sides exposed that are also coextensive with the package body for additional area for soldering. Example no-lead packages include quad flat no-lead (QFN) package that are increasingly used, but dual or single sided no-lead packages are used. Small outline no-lead (SON) packages can be used. A FCOL package can include leaded packages as well as no-lead packages.

Several processes are performed in the manufacture of semiconductor device packages. In a conventional process example for flip chip mounted semiconductor dies, a semiconductor wafer has semiconductor dies arranged in rows and columns. Conductive post connects can be plated onto the wafer. Wafer bumping can include solder deposition on the distal ends of the conductive post connects. After the wafer bumping operation, the semiconductor dies are separated from the semiconductor wafer in a singulation step. A laser, a mechanical saw, or a combination, can be used to cut through the semiconductor wafer along scribe lines between the semiconductor dies.

The separated semiconductor dies are then turned over to face a package substrate and flip chip mounted to the package substrate, for example, a conductive lead frame. A solder reflow process mechanically attaches, and electrically couples, the flip chip semiconductor dies to the lead frame by forming solder joints at the distal ends of the conductive post connects. A molding process then covers the semiconductor dies with mold compound, which can be thermoset epoxy resin. After the mold compound cures to form the package bodies for the semiconductor device packages, the molded semiconductor devices are separated into unit semiconductor device packages by a sawing operation that saws the mold compound between devices along saw streets. The completed devices are then ready for use.

Manufacture of typical semiconductor device packages requires some processing at the wafer level and further subsequent processing of unit semiconductor dies, and further requires the use of a package substrate such as a lead frame. The electrical path from a bond pad of the semiconductor die to terminals of the semiconductor device package includes solder joints between the conductive post connects and the lead frame or other package substrate. Poor solder joints, which can occur due to die misalignment issues and other process variables, can result in a high resistance path, or even an open, which is a defect that results in a scrapped device.

Alternative approaches for semiconductor device packages include face-up, wire bonded semiconductor devices. The electrical path from a bond pad to a package terminal in these wire bonded device packages includes ball bonds on the bond pad, fine bond wires, and the stitch bonds to the leads of the package substrate. The various connections, the ball bond, the bond wires, and the stitch bond, are all potential high resistance connections and areas for possible defects that include opens, shorts between the bond wires due to wire sweep during molding, bond pad pull off opens, and these defects can increase in likelihood as devices shrink. In increasingly smaller semiconductor devices and smaller packages, the spacing between bond pads, and the space between post connects or bond wires is reduced, increasing possible shorting defects.

Methods for forming semiconductor device packages with fewer components, fewer manufacturing steps, and with higher reliability, at relatively low cost, are needed.

### SUMMARY

In a described example, a semiconductor device package includes: a semiconductor die having bond pads on a device side surface, and a build-up routing layer on the semiconductor die including: connection level conductors directly contacting the bond pads; trace level conductors on the connection level conductors directly contacting distal ends of the connection level conductors; dielectric material surrounding the connection level conductors and the trace level conductors; terminals formed of portions of a top layer of the trace level conductors having a board side surface exposed from the dielectric material, wherein an electrical connection between the terminals and the bond pads is formed without a solder joint or a bond wire; and mold compound covering a portion of the semiconductor die, the trace level conductors and the connection level conductors of the build-up routing layer, wherein the board side surface of the terminals is exposed from the mold compound.

In a further described example, a method includes: forming semiconductor dies on a semiconductor wafer, the semiconductor dies having bond pads on a device side surface and having an opposing backside surface; and forming a build-up routing layer over the semiconductor wafer. Forming the build-up routing layer includes: patterning connection level conductors over the device side surface of the semiconductor dies to form post connects contacting bond pads of the semiconductor dies and extending to a distal end; forming a first layer of dielectric material over and surrounding the post connects; grinding the first layer of dielectric material to expose the distal ends of the post connects; patterning trace level conductors over the first layer of dielectric material, the trace level conductors contacting distal ends of the post connects; depositing a second layer of dielectric material over the connection level conductors and the trace level conductors; and grinding the second dielectric layer to expose a surface of the trace level conductors, portions of the exposed surface of the trace level conductors forming terminals for semiconductor device packages.

The method continues by cutting through the build-up routing layer in scribe lanes between the semiconductor dies to form trenches extending into the semiconductor wafer; backgrinding the semiconductor wafer on the backside surface of the semiconductor wafer to form openings by exposing the trenches to separate the semiconductor dies from one another; and covering the device side surface of the semiconductor dies, a portion of the routing layers, the openings between the semiconductor dies, and the board side surface of the semiconductor dies with mold compound, while the terminals formed of the trace level conductors are exposed from the mold compound.

In another described example, a no-lead semiconductor device package includes: a semiconductor die having bond pads on a device side surface and having an opposing backside surface; and a build-up routing layer over the semiconductor die, including: connection level conductors directly contacting the bond pads and forming post connects extending from the bond pads to distal ends; trace level conductors on the connection level conductors, the trace level conductors directly contacting the distal ends of the post connects; dielectric material surrounding the post connects and the trace level connection conductors; terminals formed of a portion of a top layer of the trace level conductors having a board side surface exposed from the dielectric material, wherein an electrical connection between one of the bond pads of the semiconductor die and one of the terminals is formed without a solder joint or a bond wire; and mold compound covering the semiconductor die and the build-up routing layer, a board side surface of the terminals exposed from the mold compound, the terminals of the semiconductor device package having a planar surface on the board side surface of the semiconductor device package, wherein the mold compound covering board side surface is planar and is coplanar with the terminals of the semiconductor device package.

### BRIEF DESCRIPTION OF THE DRAWINGS

FIG. 1 illustrates, in a projection view, a quad flat no-lead semiconductor device package that can be used with the arrangements.

FIGS. 2A-2B illustrate, in projection views, a semiconductor wafer with individual semiconductor dies arranged in rows and columns on a device side surface, and an individual semiconductor die from the semiconductor wafer, respectively.

FIG. 3 illustrates, in a projection view, the board side surface of a flip chip on lead semiconductor device package that can be used in an arrangement.

FIGS. 4A-4B illustrate, in a series of cross-sectional views, the major steps in manufacturing a build-up routing layer formed on a semiconductor wafer that can be used in the arrangements.

FIGS. 5A-5N illustrate, in a series of views, selected steps for forming a semiconductor device package of an example arrangement using a wafer level packaging process.

FIGS. 6A-6B illustrate in projection views two alternatives for example semiconductor device packages formed using the arrangements.

FIGS. 7A-7C illustrate a cross-section of a semiconductor wafer, a cross-section of an individual semiconductor device package of an alternative arrangement, and a top side projection view of the alternative semiconductor device package, respectively.

FIG. 8A illustrates, in a flow diagram, selected steps of a method for forming the arrangements, and FIG. 8B illustrates, in additional flow diagram, detailed steps for forming a build-up routing layer used in the method of FIG. 8A.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device can be a radio transceiver or a radar transceiver. The semiconductor device can be a receiver or a transmitter. When semiconductor devices are fabricated on a semiconductor wafer and then individually separated from the semiconductor wafer, the individual units are referred to as “semiconductor dies.” A semiconductor die is also a semiconductor device.

The term “semiconductor device package” is used herein. A semiconductor device package has at least one semiconductor die electrically coupled to terminals, and has a package body that protects and covers the semiconductor die. The semiconductor device package can include additional elements. For example, passive components such as capacitors, resistors, and inductors or coils can be included. In some arrangements, multiple semiconductor dies can be packaged together. In some approaches a semiconductor die is mounted to a package substrate that provides conductive leads, a portion of the conductive leads form the terminals for the packaged device. The semiconductor die can be mounted to the package substrate with a device side surface facing away from the substrate and a backside surface facing and mounted to a die pad of the package substrate. In wire bonded semiconductor device packages, bond wires couple conductive leads of a package substrate to bond pads on the semiconductor die. Alternatively, the semiconductor die can be mounted facing the package substrate using conductive post connects in a flip chip package. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the microelectronic device package.

The term “package substrate” is used herein. A package substrate is a substrate arranged to receive a semiconductor die and to support the semiconductor die in a completed semiconductor device package. Package substrates useful with the arrangements include conductive lead frames, molded interconnect substrates (MIS), partially etched lead frames, pre-molded lead frames, and multilayer package substrates. In some arrangements, a flip chip die mount is used, where post connects that extend from bond pads on the semiconductor device are attached by a solder joint to conductive lands on the device side surface of the package substrate. The post connects can be solder bumps or other conductive materials such as copper or gold with solder on a distal end. Copper pillar bumps can be used. In alternative arrangements using wire bonded packages, bond wires can couple bond pads on the semiconductor dies to the leads on the device side surface of the package substrate.

The term “build-up routing layer” is used herein. A build-up routing layer has multiple conductor layers in a dielectric material including trace level conductors, and has connection level conductors extending through the dielectric material between the trace level conductors. In an example arrangement, a build-up routing layer is formed over a semiconductor wafer in an additive manufacturing process. The semiconductor wafer is placed with a device side surface facing away from a wafer support, such as a wafer chuck. The additive manufacturing process begins by plating a patterned connection level conductors and then covering the connection level conductors with a layer of dielectric material. Grinding or thinning can be performed on the dielectric material to expose portions of top surface of the layer of conductors from the dielectric material. Additional plating layers can be formed to add additional levels of trace level conductors, some of which are trace layers that are coupled to other trace layers in the dielectric materials by connection level conductors, and additional dielectric material can be deposited at each trace layer level and can cover the conductors.

By using the additive or build-up manufacturing approach, and by performing multiple plating steps, multiple dielectric formation steps, and multiple grinding steps, a build-up routing layer is formed directly on the semiconductor wafer with an arbitrary number of trace level conductor layers and connection level conductor layers between and coupling portions of the trace level conductor layers. In the arrangements, the use of a build-up routing layer formed in a wafer level process eliminates the need for mounting singulated semiconductor dies to a separate package substrate. The semiconductor die bond pads are coupled by the connection level conductors and the trace level conductors in the build-up routing layer to terminals also formed by conductors in the additive plating process, so that no solder joints or wire bonds are needed to complete the packaging process. The backside of the semiconductor wafer can then be covered with mold compound to complete the packaging process at the wafer level process, eliminating the individual die processes used in prior approaches, reducing costs, and reducing the size of the resulting packages (due to the lack of the package substrate). Direct electrical connections from the bond pads of the semiconductor die to the terminals without solder joints or bond wire connections increase performance and reliability of the semiconductor device packages of the arrangements.

In an example arrangement, a build-up routing layer includes copper, gold, nickel, palladium, silver, tin or tungsten conductors that are formed by plating, and a thermoplastic material can be used as the dielectric material. Alternative materials that can be plated as the conductors or as an added plating on the conductors include gold, nickel, palladium, tin, and silver. Combinations of metals and alloys of these can be used. The connection level conductors between trace level conductor layers can be of arbitrary shapes and sizes and can include rails and pads to couple trace layers with low resistance for power and high current signals. High current signals for power semiconductor devices can be greater than a milliampere and up to several amperes. Unlike vias in a printed circuit board technology, the connection level conductors extending through the dielectric material are not formed in holes mechanically drilled through a dielectric material, which are limited in size and shape. Instead, in the arrangements, an additive build-up approach forms the connection level conductors plated during the additive manufacturing process, and thus the connection level conductors can have a variety of shapes and sizes.

In packaging semiconductor devices, mold compound may be used to partially cover components, to cover a semiconductor die, and to cover the electrical connections from the semiconductor die. This molding process can be referred to as an “encapsulation” process, although some portions of the package substrates are not covered in the mold compound during encapsulation, for example terminals and leads are exposed from the mold compound to enable electrical connections to the packaged device. Encapsulation is often a compressive molding process, where thermoset mold compound such as resin epoxy can be used. A room temperature solid or powdered mold compound can be heated to a liquid state and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together. After the molding process is complete, the individual microelectronic device packages are cut apart from each other in a sawing operation by cutting through the mold compound and package substrate in saw streets formed between the devices. Portions of the package substrate leads are exposed from the mold compound package to form terminals for the packaged semiconductor device.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

The term “quad flat no-lead” (QFN) is used herein for a type of semiconductor device package. A QFN semiconductor device package has conductive leads that are coextensive with the sides of a molded package body, and in a quad package the leads are on four sides. Alternative flat no-lead packages may have leads on two sides or only on one side. These can be referred to as “small outline no-lead” (SON) packages. No-lead semiconductor device packages can be surface mounted to a board using surface mount technology (SMT) processes.

The term “wettable flank” is used herein. In example arrangements, the terminals of a no-lead semiconductor device package are stepped or dimpled on the sides of the device package so that solder can form a joint on the side and board side surface of the terminals. The use of wettable flanks in surface mounting technology (SMT) processes aids in automated visual inspection (AVI) of solder joints, as the side solder joint is visible from the top view of the semiconductor device package, increasing reliable AVI inspection of boards. In alternative no-lead packages useful with the arrangements, a terminal of a semiconductor device package can be described as having a “non-wettable” flank. These non-wettable flank terminals have sides thar are coextensive with the mold compound of the semiconductor device package, and solder does not form joints on the non-wettable flanks. However, reliable surface mounting of the no-lead packages using terminals with non-wettable flanks is readily achieved, and the process steps for forming the semiconductor device package are slightly simpler than for the wettable flank terminals.

In example arrangements, a build-up routing layer can be formed in a two-level routing layer, alternatively a three or more-layer build-up routing layer can be formed, and package terminals are formed as a portion of a top layer of a conductor level of the build-up routing layer, the top layer is the level of conductors farthest from a semiconductor wafer. The terminals are plated in the additive manufacturing process and can be used to mount the semiconductor die to a system board. Use of the build-up routing layer formed at the wafer level eliminates the die handling and die mounting steps used in prior packaging process approaches, and eliminates the use of a lead frame or other package substate between the semiconductor dies and the package terminals. The use of the arrangements enables thinner semiconductor device packages, and eliminates a wire bond or a solder joint connection between the semiconductor die and the terminals, increasing performance and increasing reliability by reducing the risk of a failed connection or of a high resistance connection. In the arrangements, an electrical path from the bond pad on the semiconductor die to the package terminals is formed entirely from plated conductors formed directly in contact with one another, so that the materials can be the same, and the resistance of the path is relatively low, without the use of a solder joint or bond wire.

In some example arrangements, the semiconductor dies have an exposed backside surface to provide efficient thermal transfer from the semiconductor die out of the semiconductor device package during operation. Cooling, or the use of heat slugs or heat sinks can further increase thermal transfer from the semiconductor die. In alternative example arrangements, the backside of the semiconductor die is covered with mold compound.

In some example arrangements, the semiconductor die can be a power device, such as a power field-effect-transistor (“power FET”). In an arrangement for a packaged power FET, the terminals that correspond to power and ground, and in some applications, a switch node terminal, can be configured to carry currents in the milliamp to ampere range. Terminals that carry high currents can be made larger than terminals that carry control signals at lower currents, for example, to reduce resistance and increase performance. In some examples, a terminal carrying a high current can be coupled to multiple bond pads on the semiconductor die, again to reduce resistance and increase performance. Power supply terminals and ground terminals can be coupled to multiple bond pads using the trace level conductors and the connection level conductors in the build-up routing layer of the arrangements.

FIG. 1 illustrates, in a projection view from the top side, a quad flat no-lead (QFN) package that is useful with the arrangements. The QFN package 100 has terminals 110 that are coupled to a semiconductor die (not shown) inside the semiconductor device package 100. QFN packages are increasingly popular as the terminals 110, which are configured for surface mount technology (SMT) solder mounting to a board or module, are coextensive with the mold compound that forms the package body of the semiconductor device package 100. This no-lead form factor reduces the board area needed to mount the QFN package (when compared to a semiconductor device package with leads extending from the package body, such as a dual in-line package (DIP) for example). However, leaded packages can be used with the arrangements as well as no-lead packages.

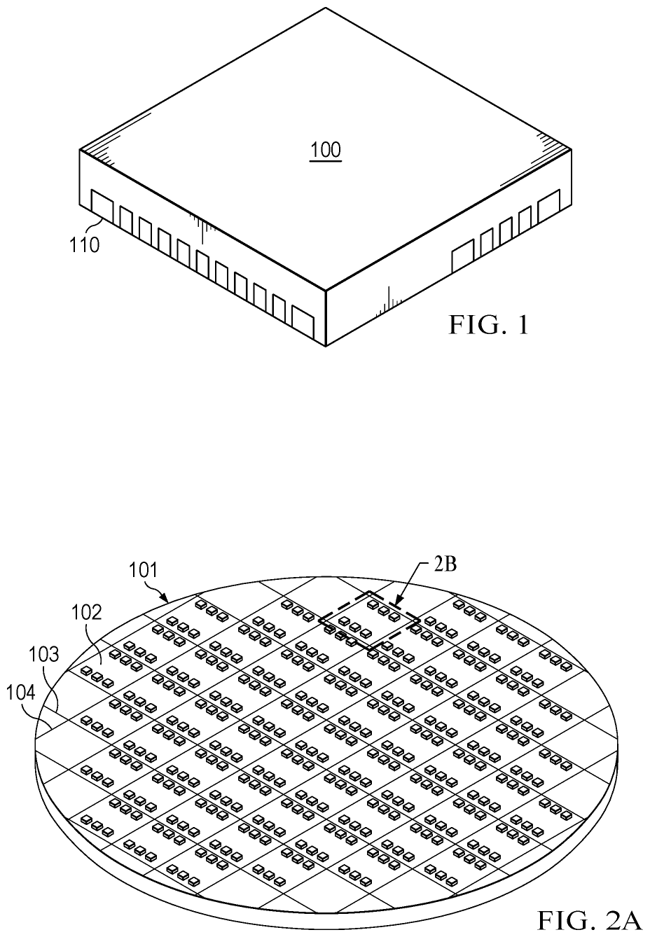

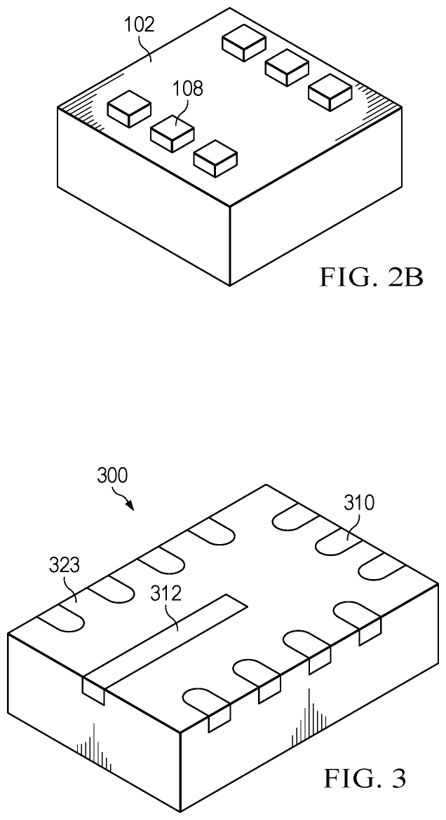

FIGS. 2A and 2B illustrate, in two projection views, a semiconductor wafer having semiconductor dies formed on it, and an individual semiconductor die, respectively. In FIG. 2A, a semiconductor wafer 101 is shown with an array of semiconductor dies 102 formed in rows and columns on a device side surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another and which run in parallel groups across the wafer 101, separate the rows and columns of the completed semiconductor dies 102, and provide areas for dicing the wafer 101 to separate the semiconductor dies 102 from one another.

FIG. 2B illustrates a single semiconductor die 102 taken from semiconductor wafer 101. Semiconductor die 102 includes bond pads 108, which are conductive pads that are electrically coupled to devices (not shown) formed in the semiconductor die 102. Not shown for clarity of illustration are under bump metallization (UBM) portions which can be formed over the bond pads to improve plating and adhesion. Materials used in UBM include nickel, gold, palladium, tin and can be used to reduce tarnish and corrosion and to retard diffusion of metals.

FIG. 3 illustrates, in another projection view from a board side, a flip chip on lead (FCOL) semiconductor device package 300. The example semiconductor device package illustrated is a HotRod™ package commercially available from Texas Instruments Incorporated. A semiconductor die (not shown in FIG. 3) inside the mold compound 323 is flip chip mounted to a lead frame (not shown in FIG. 3, inside the mold compound 323) and leads that are part of the lead frame have portions exposed from the mold compound to form terminals 310. A die attach pad 312 provides a thermal connection to the semiconductor die inside the package. The terminals 310 and die attach pad 312 are configured for SMT mounting to a board. The lead frame and terminals can be formed of copper or an alloy, other lead frame materials can be used such as Alloy 42, stainless steel, and steel. Platings for solder adhesion and for preventing tarnish or corrosion can be formed on the terminals and/or the die attach pad.

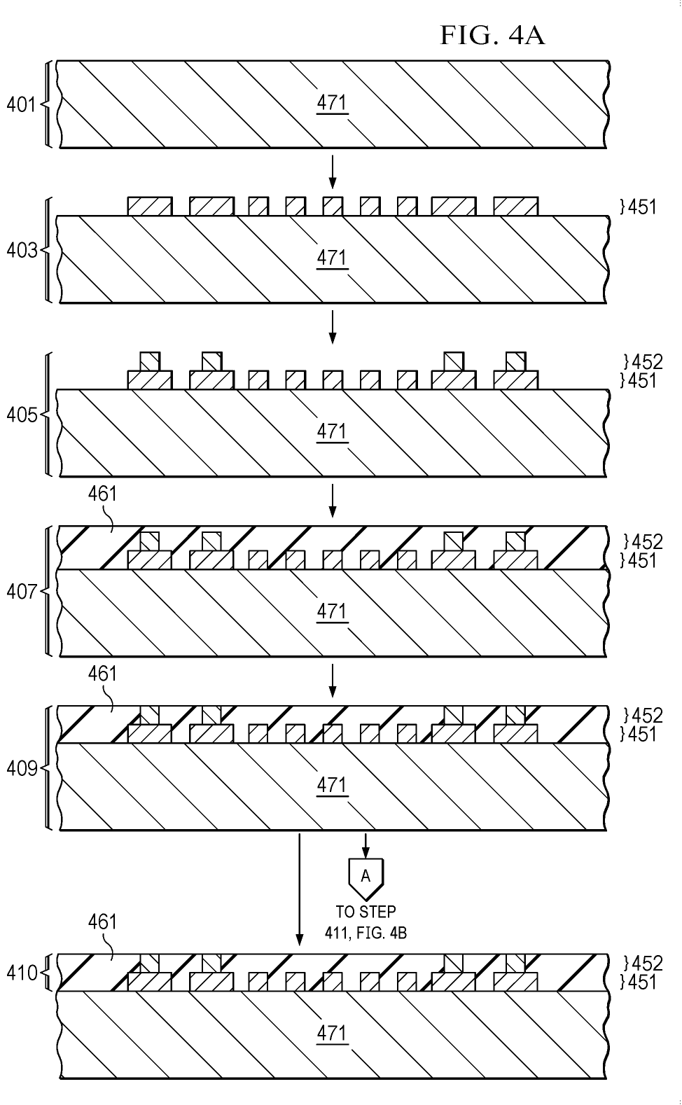

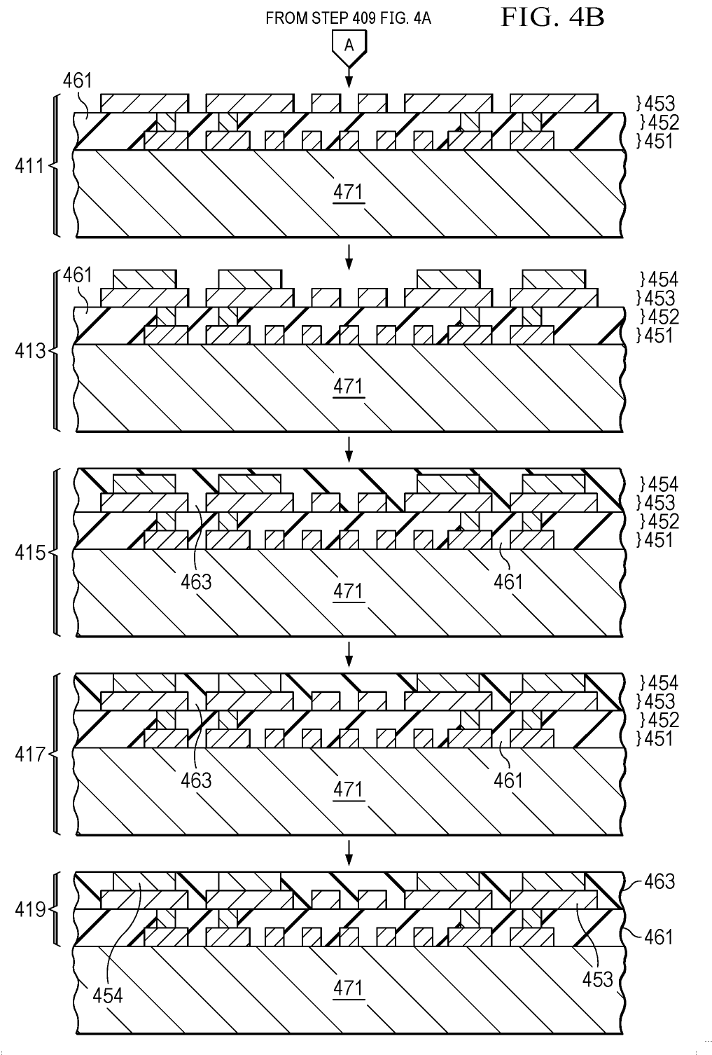

FIGS. 4A-4B illustrate, in a series of cross-sectional views, selected steps for a method for forming a build-up routing layer that is useful with the arrangements. In FIG. 4A, at step 401, semiconductor wafer 471 is readied for a plating process. The semiconductor wafer 471 has semiconductor dies with bond pads (not shown for simplicity of illustration) formed on an upper surface (as oriented in FIGS. 4A-4B).

At step 403, a first trace level conductor layer 451 is formed by plating. In an example plating process, a seed layer is deposited over the device side surface of the semiconductor wafer 471, by sputtering, chemical vapor deposition (CVD) or another deposition step. A photoresist layer (not shown for clarity of illustration) is deposited over the seed layer, exposed, developed and cured to form a pattern to be plated. Electroless or electroplating is performed using the exposed portions of the seed layer to start the plating, forming a conductor pattern according to patterns in the photoresist layer. The photoresist layer is removed and the first trace level conductor layer 451 is formed as shown.

At step 405, the plating process continues. A second photoresist layer is deposited, exposed, and developed to pattern the first connection level conductor layer 452. In this example process, by leaving the first photoresist layer in place, the second photoresist layer can be used without an intervening photoresist strip and clean step, to simplify processing. In an example process, the first trace level conductor layer 451 can be used as a seed layer for the second plating operation, to further simplify processing, as another sputter process is not performed. The first connection level conductor layer 452 acts similarly to a via in a conventional printed circuit board or laminate substrate. However, unlike vias in traditional package substrates such as PCBs, the connection level conductors 452 can be arbitrarily shaped and when patterned in correspondence with the trace level conductors, rails, tanks, or tubs can be formed in the routing layer being formed. The connection level conductors can be used to couple the semiconductor die bond pads through the build-up layer directly to terminals, as shown below, without solder joints or wire bonds between the terminals and the semiconductor dies.

At step 407, a first dielectric deposition is performed. The first trace level conductor layer 451 and the first connection level conductor layer 452 are covered in a dielectric material 461. In an example a thermoplastic material is used. In a particular example Ajinomoto build-up film (ABF) is used; in alternative examples acrylonitrile butadiene styrene (ABS), acrylonitrile styrene acrylate (ASA), or epoxy resin can be used; resins, epoxies, or plastics can be used. Ajinomoto build-up film is commercially available from Ajinomoto Co., Inc., 15-1, Kyobashi 1-chome, Chuo-ku, Tokyo, Japan 104-8315. In an example process for depositing ABF as the dielectric 461, a roll film is laminated onto the trace level conductors 451 and connection level conductors 452. The elements can be heated and a vacuum applied, the ABF softens under heat and conforms to the semiconductor wafer 471 and covers the conductors without voids. The ABF can then be cured to harden to form the dielectric material 461. In an alternative approach, liquid ABF can be applied and cured. Other dielectric materials can be used for dielectric 461.

At step 409, a grinding operation is performed on the surface of the dielectric 461 that exposes a surface of the connection level conductor layer 452 and provides conductive surfaces ready for use, or for use in additional plating operations. If the multilayer build-up routing layer is complete at this step, the method ends at step 410, leaving the first trace level conductor layer 451 and the first connection level conductor layer 452 in a dielectric material 461 over the semiconductor wafer 471.

In examples where additional trace level conductor layers and additional connection level conductor layers are needed, the method continues, leaving step 409 and transitioning to step 411 in FIG. 4B. The multilayer build-up routing layer is now on semiconductor wafer 471 with first trace level conductor layer 451 and connection level conductor layer 452.

At step 411, a second trace level conductor layer 453 is formed by plating using the same processes as described above with respect to step 405. A seed layer for the additional plating operation is deposited and a photoresist layer is deposited and patterned, and the plating operation forms the second trace level conductor layer 453 over the dielectric 461, with portions of the second trace level conductor layer 453 electrically connected to the first connection level conductor layer 452.

At step 413, a second connection level conductor layer 454 is formed using an additional plating step on the second trace level conductor layer 453. The second connection level conductor layer 454 can be plated using the second trace level conductor layer 453 as a seed layer, and without the need for removing the preceding photoresist layer, simplifying the process.

At step 415, a second molding operation is performed to cover the second trace level conductor layer 453 and the second connection level conductor layer 454 in a layer of dielectric 463. The multilayer build-up routing layer at this stage has a first trace level conductor layer 451, a first connection level conductor layer 452, a second trace level conductor layer 453, and a second connection level conductor layer 454, portions of the layers are electrically connected together to form conductive paths through the dielectric layers 461 and 463.

At step 417, the dielectric layer 463 is mechanically ground in a grinding process or is chemically etched to expose a surface of the second connection level conductor layer 454. At step 419 the example method ends by leaving the build-up routing layer on semiconductor wafer 471, including the trace level conductor layers 451, 453, and connection level conductor layers 452 and 454 in dielectric layers 461, 463. The steps of FIGS. 4A-4B can be repeated to form multilayer build-up routing layers in arrangements having more layers, by performing plating of a trace level conductor layer, plating of a connection level conductor layer, adding a dielectric material covering the layers, and grinding, repeatedly. In the arrangements, a portion of the top level of conductor in forms the terminals for the semiconductor device package.

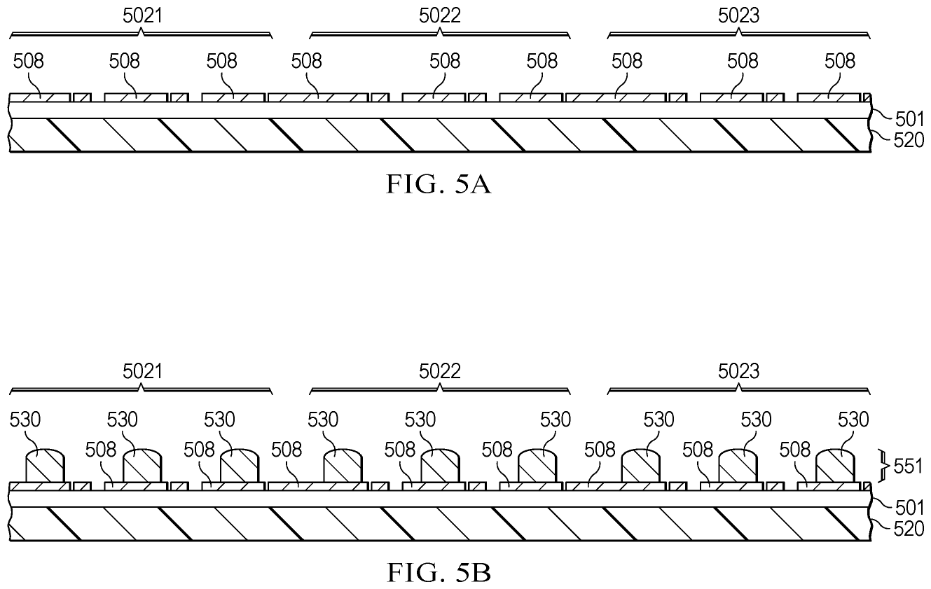

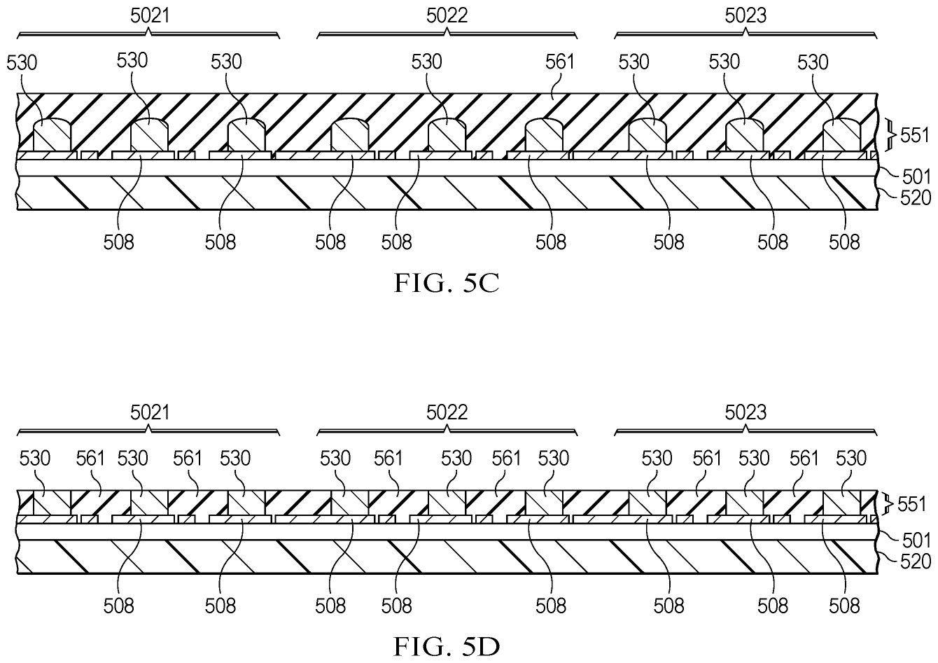

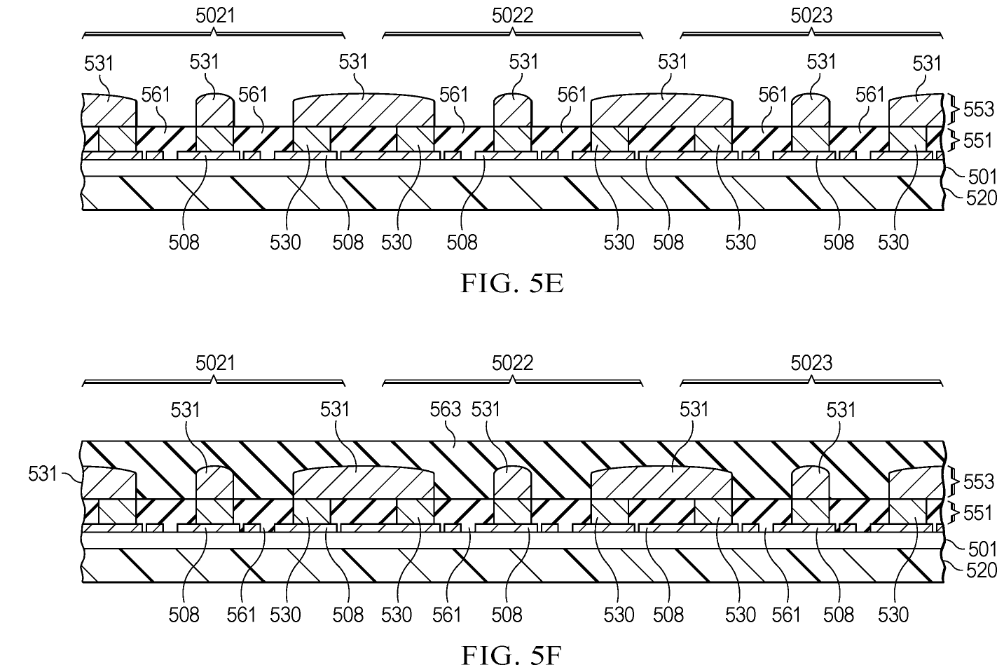

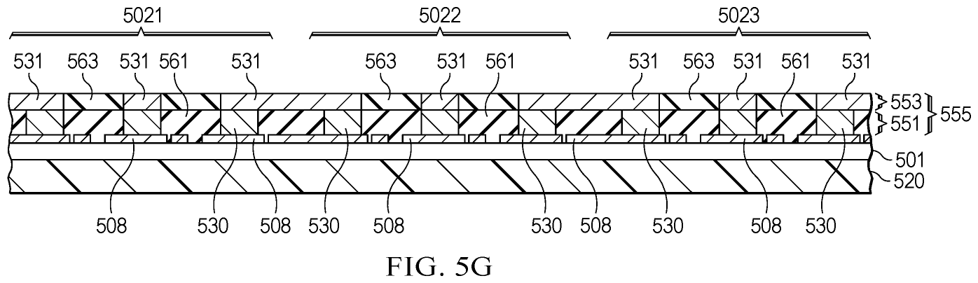

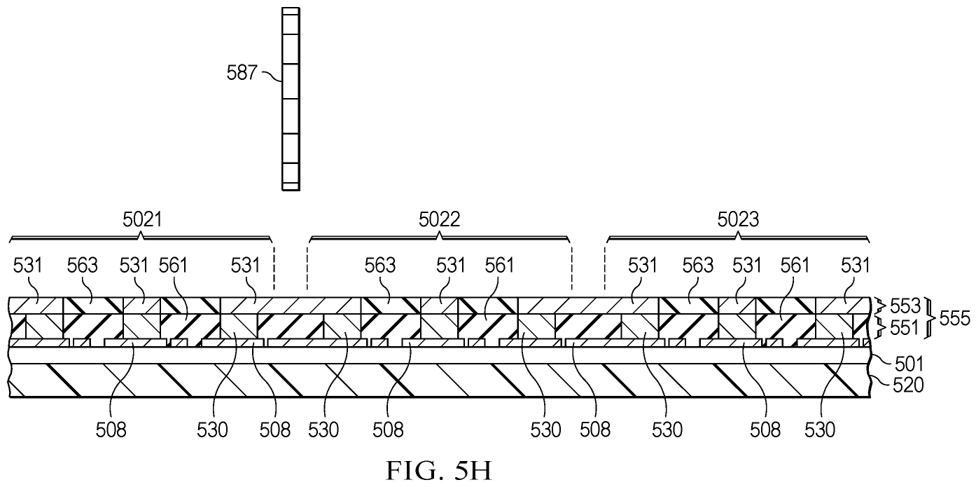

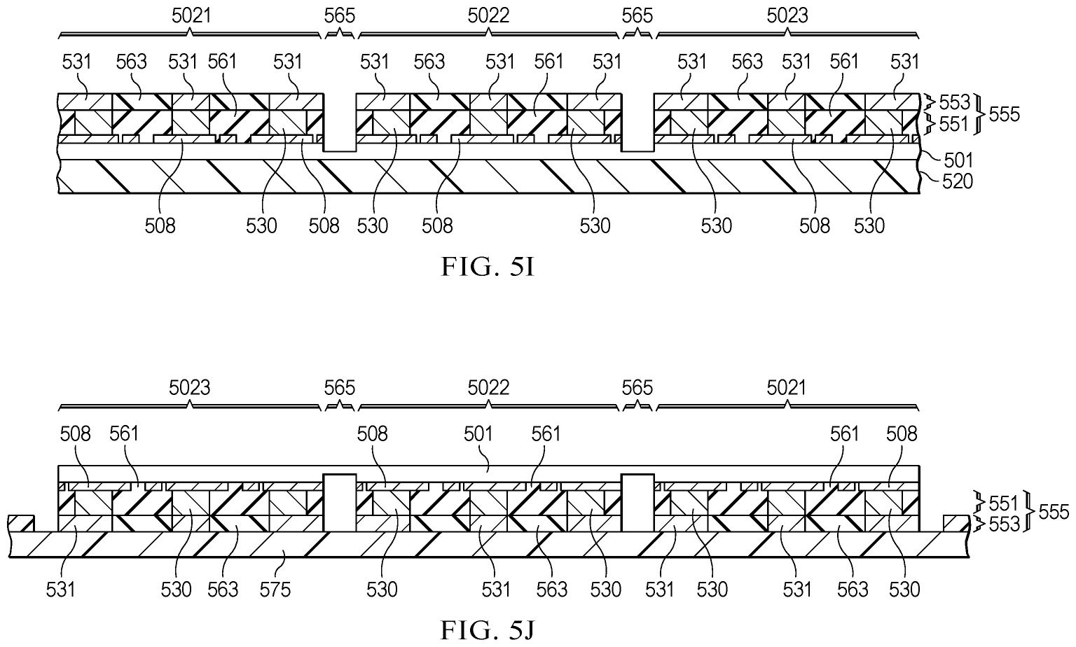

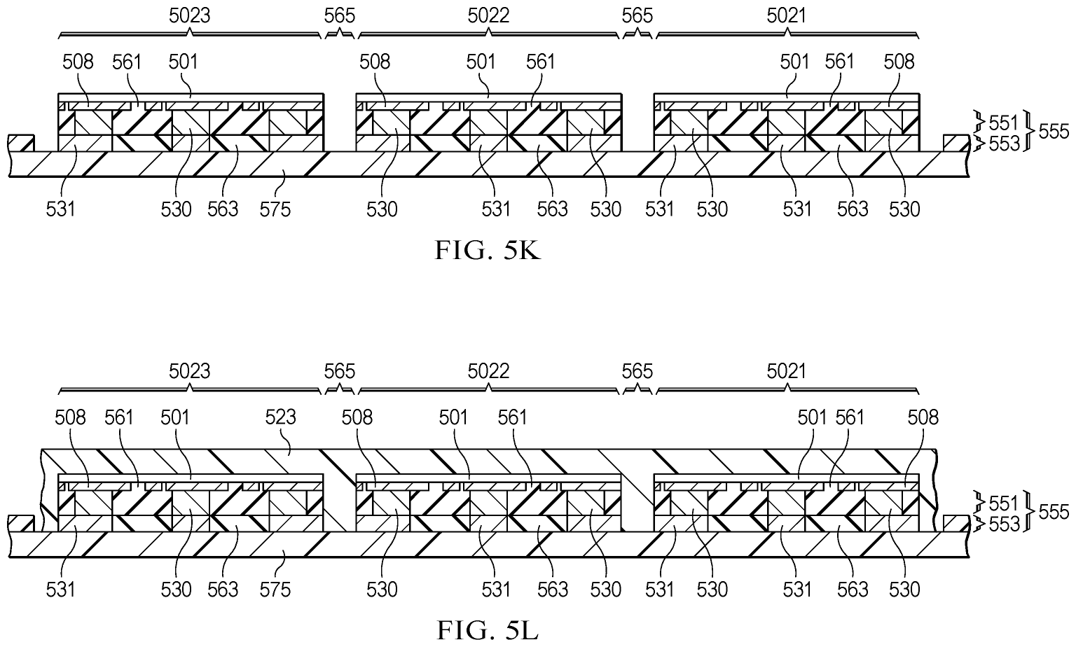

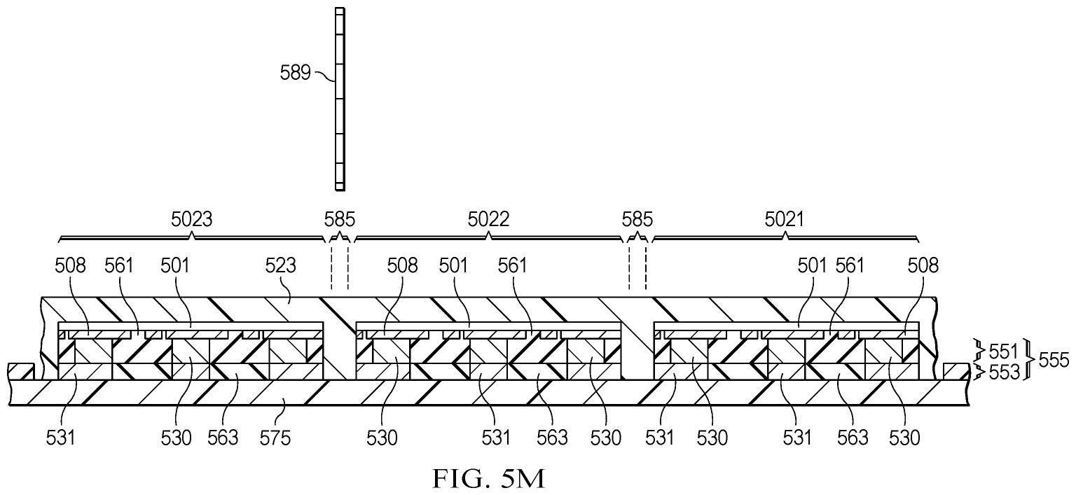

FIGS. 5A-5L illustrate, in a series of views, a method for the build-up additive manufacturing process of FIGS. 4A-4B used in forming an arrangement for a wafer level semiconductor device package.

In FIG. 5A, a cross-sectional view illustrates a semiconductor device wafer 501, similar to semiconductor device wafer 101 in FIG. 2A. The semiconductor wafer 501 is shown on a wafer support 520, which can be a wafer chuck such as vacuum chuck. Bond pads 508 of semiconductor dies 5021, 5023, 5023, formed in the semiconductor wafer 501 are shown exposed on a device side surface of the semiconductor wafer 501. The semiconductor dies 5021, 5022, 5023 can be similar to semiconductor dies 102 in FIGS. 2A-2B. Semiconductor dies 5021, 5022 and 5023 will be replicated across the semiconductor wafer in rows and columns, see semiconductor wafer 101 with dies 102 in FIG. 1A.

FIG. 5B illustrates the semiconductor device wafer 501 of FIG. 5A after additional processing. In FIG. 5B, a connection level conductor layer 551 is shown formed by plating. In an example, copper or copper alloy is used to form the connection level conductor layer 551, which form copper pillars extending from the bond pads 508 to a distal end. The conductors can be copper, gold, nickel, palladium, tin, silver, or combinations or alloys thereof. The processes of FIG. 4A can be used, a seed layer can be deposited over the semiconductor device wafer 501, a photoresist layer can be deposited on the seed layer and patterned to expose the bond pads 508, and an electroless plating or electroplating can be used to form the connection level conductor layer 551. Post connects 530 form direct connections to the bond pads 508. The semiconductor dies 5021, 5022, 5023 are replicated units each having post connects 530 extending from bond pads 508 in the connection level conductor layer 551.

FIG. 5C illustrates the semiconductor device wafer 501 on the support 520 after dielectric material 561 is formed over the connection level conductor layer 551 with post connects 530. The dielectric 561 can be ABF, ABS, ASA, epoxy resin, or thermoplastic material. In an example ABF lamination process, rolled ABF film is laid over the post connects formed in the connection level conductor layer 551, and heat and vacuum are applied to cause the soft ABF to conform to the semiconductor wafer 501 and the post connects 530, without voids. The ABF is then cured to harden the material for further processing.

FIG. 5D illustrates, in another cross-sectional view, the elements of FIG. 5C after further processing. The semiconductor wafer 501 is on support 520 with bond pads 508 and the post connects 530 on the bond pads 508. The semiconductor dies 5021 are shown after a grinding process, such a chemical mechanical polishing process, removes dielectric material 561 from the post connects 530 and planarizes the surface for further processing.

FIG. 5E illustrates, in a further cross-sectional view, the elements of FIG. 5D after additional processing. The semiconductor wafer 501 is shown on support 520 with the post connects 530 extending from the bond pads 508. The dielectric material 561 is shown surrounding the post connects 530. A second conductor layer 553 is shown patterned to form trace level connections 531 formed over the dielectric 561. The trace level connections 531 are formed by another electroless plating or electroplating process on the top surface of the dielectric layer 561. The trace level connections 531 can be used as a routing layer to route the signals from the bond pads 508, to make connections or to relocate signals. In the arrangements, portions of the trace level connections 531 will form the terminals for the semiconductor device package. The semiconductor dies 5021, 5022, 5023 are shown as before.

FIG. 5F illustrates, in a cross-sectional view, the elements of FIG. 5E after an additional dielectric layer is formed on the conductor layer 553. The dielectric layer 563 now extends above the trace level connections 531 in the conductor layer 553. The post connects 530 extend from the bond pads 508 to the trace level connections 531 in conductor 553. The semiconductor dies 5021, 5022, 5023 are shown. Semiconductor wafer 501 is shown on support 520.

FIG. 5G illustrates, in a further cross-sectional view, the elements of FIG. 5F after another grinding step. The semiconductor wafer 501 is on support 520 with semiconductor dies 5021, 5022, and 5023. The dielectric 563 is removed over the conductor layer 553, exposing and planarizing the surfaces of the trace level connections 531. The grinding process can be performed by another CMP process, for example. This completes forming the build-up routing layer 555 which includes the conductor layers 551, 553 which form the post connects 530 and the trace level connections 531.

FIG. 5H illustrates in a cross-sectional view, the elements of FIG. 5G after additional processing. The semiconductor wafer 501 is shown on the support 520 and include the semiconductor dies 5021, 5022, 5023. The build-up routing layer 555 is shown over the semiconductor wafer 501. In a sawing operation, the saw blade 587 is passed along scribe lanes between the semiconductor dies 5021, 5022, and 5023. The sawing operation cuts through the build-up routing layer 555 including the conductor layer 553, the conductor layer 551, and the dielectric 563, and partially into the semiconductor wafer 501. The sawing operation can be by a mechanical saw blade 587 as shown, by laser cutting, or by a combination. The trace level connections 531 that are shown extending between semiconductor dies 5021, 5022, and 5022, 5023 are cut through so that the unit semiconductor dies are no longer connected by the trace level connections 531 in conductor layer 553. The semiconductor wafer 501 is partially cut, but the semiconductor dies 5021, 5022, 5023 remain connected by the remaining portion of the semiconductor wafer 501.

FIG. 5I illustrates the elements of FIG. 5H in another cross-sectional view, illustrating the results of the sawing operation shown in FIG. 5H. Trenches 565 are formed in the saw streets between 5021, 5022, and 5023, and extend into the semiconductor wafer 501. The semiconductor wafer 501 is shown sitting on the support 520. The build-up routing layer 555, including the conductor layers 553, 555 and dielectric 563, is cut through by trenches 565, which extend into the surface of the semiconductor wafer 501, but not through it, so that the semiconductor dies 5021, 5022 and 5023 remain connected at this stage of the process.

FIG. 5J illustrates, in another cross-sectional view, the semiconductor wafer 501 and the other elements of FIG. 5J are shown turned over from the position in FIG. 5I and mounted on a wafer mounting tape 575, which can be supported in a frame or bracket. Wafer mounting tape 575 is a peelable or removeable adhesive tape that supports the semiconductor wafer 501 for additional processing. The wafer mounting tape can have an ultra-violet (UV) release feature or can be removed by mechanical peeling. Build-up routing layer 555 is shown with the trace level connections 531 and dielectric 563 in contact with the wafer mounting tape, and the trenches 565 are shown extending from the wafer mounting tape 575. Semiconductor dies 5021, 5022, and 5023 are shown still turned over from FIG. 5I but connected by the uncut portion of the semiconductor wafer 501. The post connects 530 extend from the bond pads 508 on the semiconductor wafer 501, and to the trace level connections 531. The trenches 565 extend through the dielectric 563 and the trace level connections 531 and the connection level connections of post connects 530 and into the surface of the semiconductor wafer 501, but not through it.

FIG. 5K illustrates in a cross-sectional view the semiconductor wafer 501 and the other elements shown in FIG. 5J after a wafer backgrinding process. The semiconductor wafer 501 is thinned in a grinding process, such as a CMP backgrinding process, and the trenches 565 are opened from the backside, so that the unit semiconductor dies 5023, 5022 and 5021 are now separated from one another and mounted to the semiconductor mounting tape 575. Each of the semiconductor dies 5023, 5022, and 5021 has the bond pads 508 connected by the connection level conductors of the build-up routing layer 555 forming the post connects 503 to the trace level connections 531. The mounting tape 575 remains in place and supports the devices for further processing.

FIG. 5L illustrates, in a cross-sectional view, the elements of FIG. 5K after a molding process. Mold compound 523 is shown deposited over the semiconductor dies 5023, 5022, 5021 covering the backside of the semiconductor wafer 501 and the exposed sides of the build-up routing layer 555 in the trenches 565. The molding compound forms a protective package body for the semiconductor dies and the build-up routing layer 555, with the bond pads 508 directly connected by the conductor layers 551, 553 to the trace level connections 531. Mold compound 523 can be formed using electronic mold compound (EMC), an epoxy resin material, in a transfer mold tool, for example. Powdered or solid mold compound is placed in the tool and heated to a liquid state, then formed under mechanical pressure by a ram into runners that fill the mold where the mounting tape 575 holds the elements. The mold compound is allowed to cool and form a solid plastic.

FIG. 5M illustrates, in another cross-sectional view, the elements of FIG. 5L during a singulation sawing process. A dicing saw 589 has a rotating blade that cuts through the mold compound 523 in saw streets 585 between the semiconductor dies 5023, 5022, 5021 while the mounting tape 575 supports the devices. The dicing saw 589 traverses the saw streets along grids or arrays of devices to form unit semiconductor device packages with the mold compound 523 protecting the back side of the packaged devices, and trace level connections 531 forming terminals of the packaged devices.

FIG. 5N illustrates in a cross-sectional vies a completed semiconductor device package 500 formed by removing a packaged semiconductor die (see 5021, 5022, or 5023 in FIG. 5M) from the semiconductor mounting tape (see 575 in FIG. 5M) after the sawing operation shown in FIG. 5M. The trace level connection conductors 531 now have exposed surfaces that form terminals 510 for the completed semiconductor device package 500. The dielectric 563 surrounds the conductors on the device side surface of the semiconductor device package (the bottom surface as the semiconductor device package 500 oriented in FIG. 5N) and the mold compound 523 protects the opposing back side surface of the semiconductor device package 500. The build-up routing layer 555 is shown with the connection level conductors 551 forming the post connects extending from bond pads 508 of the semiconductor wafer 501, and portions of the trace level conductors 553 (the top level of conductors relative to the semiconductor die) forming the terminals 510. The terminals 510 are directly connected to the bond pads 508 by the trace level conductors 553 and the connection level conductors 551. In alternative arrangements, the build-up routing layer 555 can have additional layers of trace level conductors and connection level conductors, such as are shown in FIGS. 4A-4B.

Using the arrangements, a wafer level process for forming a semiconductor device package is provided. A build-up routing layer is formed directly on the semiconductor dies while at the wafer level, and the conductors within the build-up routing layer provide a path from the terminals of the semiconductor device package directly to the bond pads of the semiconductor dies without the need for a solder joint to couple the devices and without the use of bond wires, ribbons or other connectors. The build-up routing layer is formed directly on the semiconductor wafer using additive plating and dielectric deposition processes, without the need for a package substrate or lead frame, reducing the components in the completed device, and reducing costs. Because there are no solder joints or wire bonds in the completed semiconductor device package, reliability issues associated with shorts, opens, wire sweep, misalignment of solder joints with lead frames, and other common defects are eliminated. The direct connection from the terminals of the packaged devices to the bond pads of the semiconductor die is of relatively low resistance (compared to solder joints and wire bond connections), and has high reliability and ease of manufacture. Because the steps for forming the semiconductor device packages are all performed at the wafer level, the need for handling individual semiconductor dies in intermediate steps (such as are used in package substrates with flip chip or wire bonding connections) is reduced or eliminated, simplifying the equipment needed to form the semiconductor device packages, further reducing costs.

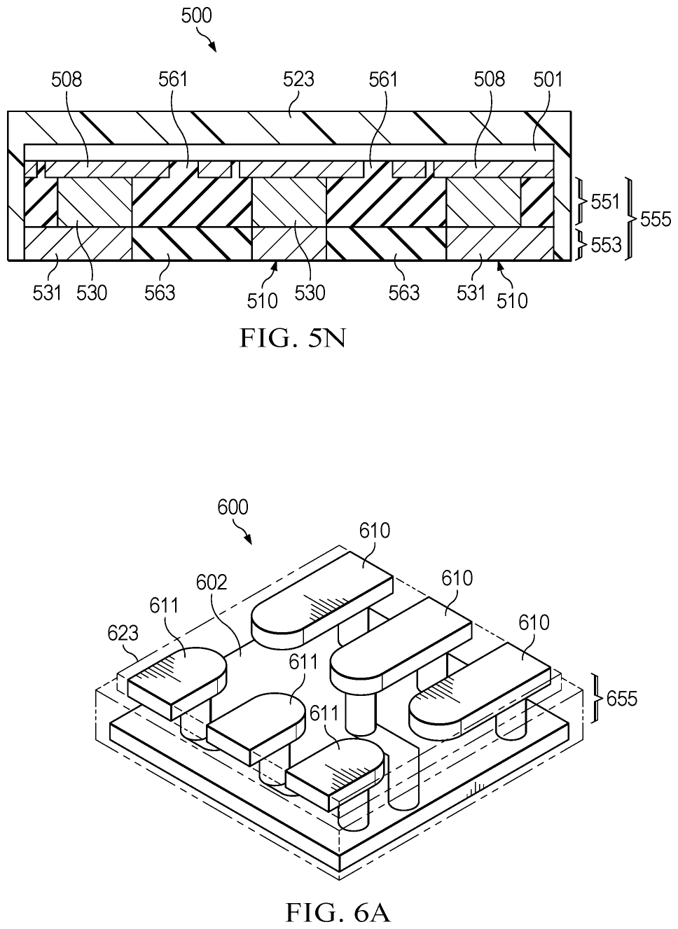

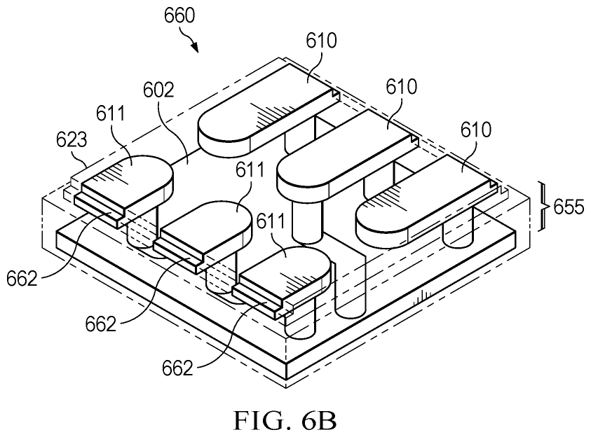

FIGS. 6A-6B illustrate, in projections, two alternative semiconductor device packages formed using the arrangements. FIG. 6A illustrates a completed semiconductor device package 600 of an arrangement that is similar to the semiconductor device package 500 shown in FIG. 5N, after an additional etching step removes mold compound from the terminals. In FIG. 6A, the illustration is a projection view with some parts of a mold compound 623 shown transparent to better illustrate the features. The example semiconductor device package of FIG. 6A is a non-wettable flank QFN package. The projection view of FIG. 6A is taken from a board side surface and shows terminals 610 and 611, which are formed of trace level connections in the build-up routing layer 655. The terminals 610 form a first set of terminals, with larger area than the terminals 611, which form a second set of terminals. The terminals 610 can be configured to carry high current, such as greater than 1 milliampere and up to several amperes. As shown in FIG. 6A, the conductors in the build-up routing layer 655 can be used to connect multiple bond pads (not shown for simplicity of illustration) on the semiconductor die 602 or to connect some of multiple terminals 610 or 611 together, providing additional flexibility in the semiconductor device package by enabling additional connections between the semiconductor die and the terminals 610 or 611. In the example semiconductor device package 600 of FIG. 6A, the terminals 610 are configured to carry more current than the terminals 611, and are larger in area. The terminals 610 can be configured to be coupled to a voltage supply, a ground potential, or a switch node in a power FET application, for example. The terminals 611, which are smaller in area, can be configured to carry control signals, or other lower current inputs or outputs of the semiconductor die 602. The build-up routing layer 655 can have additional layers of trace level connection conductors and connection level conductors (not shown) formed by the plating and dielectric deposition steps shown in FIGS. 4A-4B and described above to provide a signal redistribution function, allowing mapping of semiconductor die bond pads to terminals 610 and 611 of the semiconductor device package 600 that are at different positions or are on different sides of the packaged device, providing additional design freedom for the semiconductor device package 600 or for the semiconductor die 602.

The terminals 610, 611 in FIG. 6A are exposed from the mold compound 623 by an etch process after the mold steps (see FIGS. 5L-5N, mold compound 523 is formed over the semiconductor device wafer and then sawed through). The etch process exposes the sides of the terminals 610, 611 from the mold compound and forms sides that are coextensive with the mold compound.

FIG. 6B illustrate, in another projection view, an alternative semiconductor device package formed using the arrangements. FIG. 6B illustrates a completed semiconductor device package 660 of an arrangement that is similar to the semiconductor device package 600 shown in FIG. 6A, after an additional etching step removes forms a stepped edge on the terminals. In FIG. 6B, the illustration is a projection view with some parts of a mold compound 623 shown transparent to better illustrate the features. The example semiconductor device package of FIG. 6B is a wettable flank QFN package. A stepped edge 662 is formed on the terminals 610, and 511. The wettable flank formed by the stepped edge 662 aids in soldering the semiconductor device package 660 to a board, using surface mount technology (SMT) for example. The projection view of FIG. 6B is taken from a board side surface and shows terminals 610 and 611, which are formed of trace level connections in the build-up routing layer 655. As shown in FIG. 6B, the conductors in the build-up routing layer 655 can be used to connect multiple bond pads (not shown for simplicity of illustration) on the semiconductor die 602 or to connect some of multiple terminals 610 or 611 together, providing additional flexibility in the semiconductor device package by enabling additional connections between the semiconductor die and the terminals 610 or 611. In the example semiconductor device package 660 of FIG. 6B, the terminals 610 are configured to carry more current than the terminals 611, and are therefore larger in area. The terminals 610 can be configured to be coupled to a voltage supply, a ground potential, or a switch node in a power FET application, for example. The terminals 611, which are smaller in area, can be configured to carry control signals, or other lower current inputs or outputs of the semiconductor die 602. The build-up routing layer 655 can have additional layers of trace level connection conductors and connection level conductors (not shown) formed by the plating and dielectric deposition steps shown in FIGS. 4A-4B and described above to provide a signal redistribution function, allowing mapping of semiconductor die bond pads to terminals 610 and 611 of the semiconductor device package 660, providing additional design freedom for the semiconductor device package 600 or for the semiconductor die 602.

The terminals 610, 611 in FIG. 6B are exposed from the mold compound 623 by an etch process after the mold steps (see FIGS. 5L-5N, mold compound 523 is formed over the semiconductor device wafer and then sawed through). The etch process used in forming the semiconductor package 660 in FIG. 6B exposes the sides of the terminals 610, 611 from the mold compound and forms stepped sides that provide the wettable flanks. Solder can attach to the sides of the terminals 610, 611 in FIG. 6B, and the solder joints are visible from a board side surface, which aids in AVI inspection of boards formed using the semiconductor device package 660.

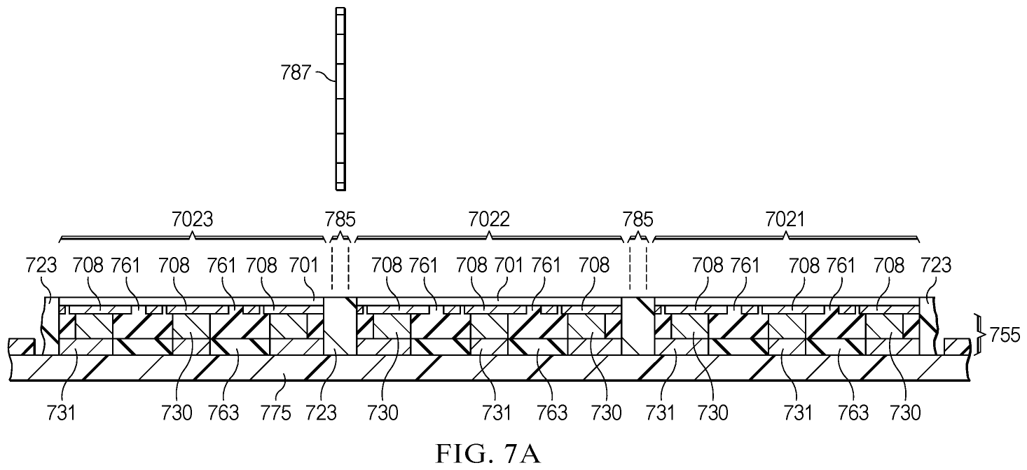

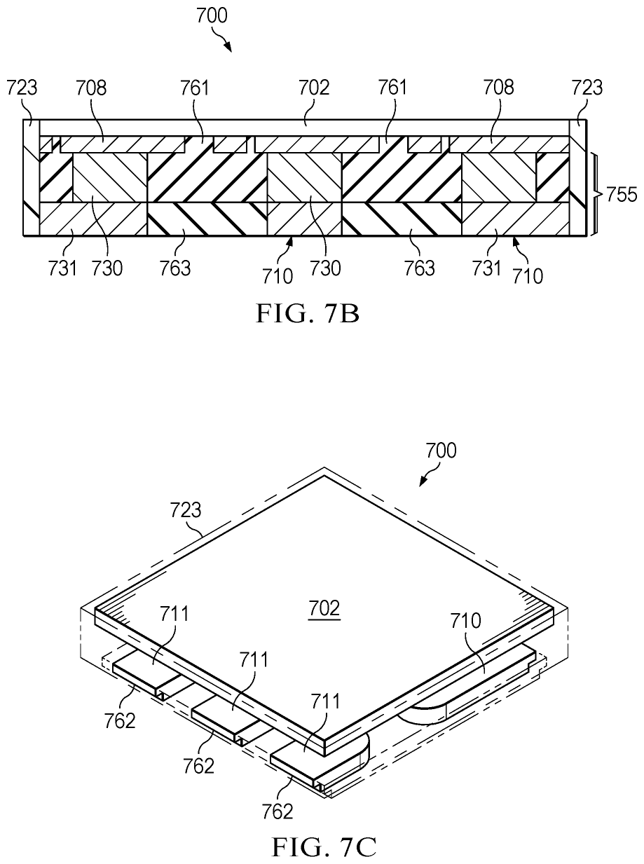

FIGS. 7A-7C illustrate an alternative arrangement for a semiconductor device package formed using the methods described with respect to FIGS. 5A-5N.

In FIG. 7A, a cross-sectional view illustrates semiconductor dies 7023, 7022 and 7021 mounted on a semiconductor wafer mounting tape 775. The semiconductor wafer 701 is shown with a build-up routing layer 755 formed over the semiconductor dies 7023, 7022, 7021, and the bond pads 708 are directly coupled to trace level connections 731 by connection level conductors 730 formed in the build-up routing layer 755. The mounting tape 775 supports the devices after a molding operation formed mold compound 723 in the saw streets 787 between the semiconductor dies 7023,7022 7021.

FIG. 7A is similar to FIG. 5L described above, except that the backside surfaces of the semiconductor dies 7023, 7022 and 7021 are now exposed from the mold compound 723, so that the backside surfaces of the semiconductor dies are not covered by the mold compound 723. This arrangement enables improved thermal dissipation of the semiconductor dies in operation. Air or liquid cooling can be applied to the completed packaged devices, alternatively heat slugs or heat sinks can be attached to the backside surface of the semiconductor dies 7023, 7022 and 7021. Each of the semiconductor dies is a replicated unit on the semiconductor wafer 701. The build-up routing layer 755 has the trace level conductors and the connection level conductors formed on the semiconductor wafer 701 and coupling the bond pads on the semiconductor wafer 701 to connection level conductors 730 and to the trace level conductors 731.

A saw blade 787 is shown in FIG. 7A cutting along the saw streets 785 between the devices, the saw blade 787 will cut through the mold compound 723 in the saw streets 785 and separate the semiconductor dies 7023, 7022 and 7021 one from another to form individual semiconductor device packages.

FIG. 7B illustrates a unit semiconductor device package 700 formed by removing a semiconductor die (such as 7021, 7022 or 7023 in FIG. 7A) after the sawing operation simulates the devices one from another. The mold compound 723 is shown protecting the sides or edges of the semiconductor die 702 and the build-up routing layer 755 over the semiconductor dies 702. The semiconductor die 702 has an exposed backside surface that provides for thermal dissipation of heat from the semiconductor die 702 in operation. Terminals 710 are formed from a portion of the top conductor of the trace level conductors in the build-up routing layer 755 and are configured for surface mounting to a system board or module. The bond pads 708 of the semiconductor die 702 are directly couped to the terminals 710 and use of the arrangements provide a low resistance path from the terminals to the bond pads without the need for solder joints or bond wires, and the use of the build-up routing layers 755 to form the packaged semiconductor device 700 eliminates the need for a package substrate and for the intermediate process steps on individual semiconductor dies 702.

FIG. 7C illustrates, in a projection view, the completed semiconductor device package 700 from a top side view. The semiconductor device package 700 is shown with terminals 711 having a stepped edge 762 forming a wettable flank QFN semiconductor device package. In an alternative (not shown), a non-wettable flank can be formed on the terminals 711, and 710. The backside surface of the semiconductor die 702 is exposed form the mold compound 723 to form a thermal pad for thermal dissipation, while the mold compound 723 protects the sides and edges of the semiconductor device package. Heat sinks or heat slugs can be mounted on the backside surface of the semiconductor die 702, or forced air or other coolant can be circulated over the packaged semiconductor device to provide additional thermal dissipation. The board side view of semiconductor device package 700 (not shown) will be similar to that for semiconductor device packages 600, 660 shown in FIGS. 6A-6B, with no-lead terminals configured for surface mounting to a board or module.

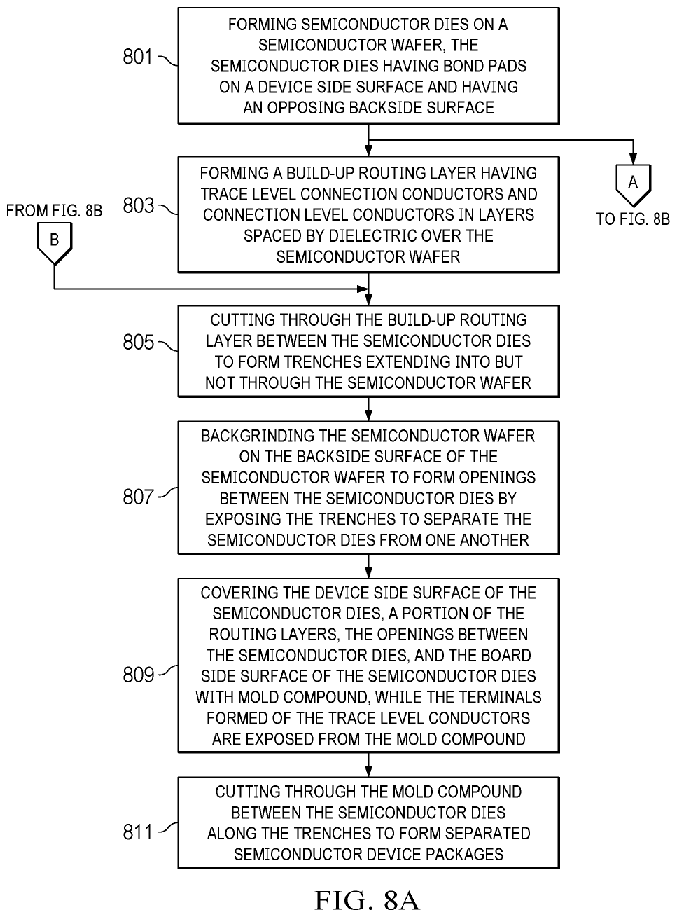

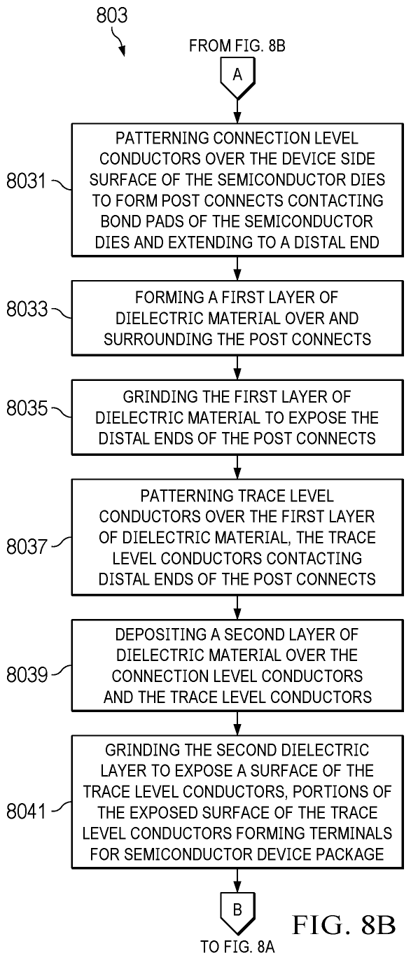

FIG. 8A illustrates, in a flow diagram, major steps for forming an arrangement. The method begins in step 801 by forming semiconductor dies on a semiconductor wafer, the semiconductor dies having bond pads on a device side surface and having an opposing backside surface. (See, for example, FIG. 5A, semiconductor dies 5021, 5022, and 5023, and bond pads 508).

At step 803, the method continues by forming a build-up routing layer having trace level connection conductors and connection level conductors in layers spaced by dielectric over the semiconductor wafer (see FIGS. 4A-4B, and FIGS. 5B-5G with build-up routing layer 555, for example).

At step 805, the method continues by cutting through the build-up routing layer between the semiconductor dies to form trenches extending into but not through the semiconductor wafer. (See FIGS. 5H, and 5I, with saw 587 forming trenches 565). At step 807, the method continues by backgrinding the semiconductor wafer on the backside surface of the semiconductor wafer to form openings between the semiconductor dies by exposing the trenches to separate the semiconductor dies from one another. (See FIGS. 5J-5K, trenches 565).

At step 809, the method continues by covering the device side surface of the semiconductor dies, a portion of the build-up routing layer, the openings between the semiconductor dies, and the board side surface of the semiconductor dies with mold compound, while the terminals formed of the trace level conductors are exposed from the mold compound. (See FIG. 5L, mold compound 523). At step 811, the method completes by cutting through the mold compound between the semiconductor dies along the trenches to form separated semiconductor device packages. (See FIG. 5M with the saw blade 589 and the semiconductor device package 500 in FIG. 5N, see also the semiconductor device package 600 in FIG. 6).

FIG. 8B expands the step 803 in FIG. 8A by describing the details for forming the build-up routing layer in selected steps. The method of FIG. 8B begins by transitioning from step 801 in FIG. 8A, and then by patterning connection level conductors over the device side surface of the semiconductor dies to form post connects contacting bond pads of the semiconductor dies and extending to a distal end. (See, for example, FIG. 5B, post connects 530 are formed in conductor layer 551).

The method continues to step 8033, by forming a first layer of dielectric material over and surrounding the post connects. (See, for example, FIG. 5C, dielectric layer 561 is formed over and surrounding post connects 530).

The method then continues to step 8035, by grinding the first layer of dielectric material to expose the distal ends of the post connects. (See, for example, FIG. 5D, where the ends of post connects 530 are exposed from dielectric 561).

The method continues to step 8037, by patterning trace level conductors over the first layer of dielectric material, the trace level conductors contacting distal ends of the post connects. (See, for example, FIG. 5E, where trace level conductors 531 are formed in conductor layer 553.)

The method continues to step 8039, by depositing a second layer of dielectric material over the connection level conductors and the trace level conductors. (See, for example, dielectric layer 563 formed over the trace level connections 531 in conductor layer 553).

The method continues at step 8041, by grinding the second dielectric layer to expose a surface of the trace level conductors, portions of the exposed surface of the trace level conductors forming terminals for semiconductor device packages. (See, for example, FIG. 5G, where build-up routing layer 555 is completed over the semiconductor wafer 501 by grinding the second dielectric layer 563 and the trace level connections 531).

The method of FIG. 8B then transitions to step 805 in FIG. 8A, to complete the formation of the semiconductor device packages as described above.

The use of the arrangements provides a wafer level process for forming semiconductor device packages. A build-up routing layer is formed over a semiconductor wafer with conductors formed on the bond pads of semiconductor dies on the device side surface of the semiconductor wafer. The build-up routing layer is formed using additive manufacturing to plate post connects extending from the bond pads, and trace level connections formed on the distal ends of the post connects, with dielectric material deposited surrounding and protecting the conductors. Portions of the trace level connections form terminals for the semiconductor device packages. Trenches formed in the build-up routing layer and extending partially into the semiconductor wafer are formed. A grinding operation to thin the semiconductor wafer opens the trenches between the semiconductor dies. Mold compound is applied to the backside of the semiconductor wafer, filling the trenches between the semiconductor devices. A dicing saw cuts through the mold compound between the devices and separates the completed semiconductor device packages from one another. The terminals formed in the trace level connections of the build-up routing layer form no-lead terminals for the semiconductor device package. The arrangements are formed using methods, materials and tooling for making the devices that are cost effective. Use of the arrangements forms semiconductor device packages at the wafer level without the use of package substrates, solder joints, or bond wires, eliminating materials and steps used in conventional package processes.

Modifications are possible in the described arrangements, and other alternative arrangements are possible within the scope of the claims.

What is claimed is:

1. A method, comprising:
forming semiconductor dies on a semiconductor wafer, the semiconductor dies having bond pads on a device side surface and having an opposing backside surface;
forming a build-up routing layer over the semiconductor wafer by performing:
patterning connection level conductors over the device side surface of the semiconductor dies to form post connects directly contacting the bond pads of the semiconductor dies and extending to a distal end;
forming a first layer of dielectric material over and surrounding the post connects;
grinding the first layer of dielectric material to expose the distal ends of the post connects;
patterning trace level conductors on the first layer of dielectric material, the trace level conductors directly contacting distal ends of the post connects;
depositing a second layer of dielectric material over the connection level conductors and the trace level conductors; and
grinding the second dielectric layer to expose a surface of the trace level conductors, portions of the exposed surface of a top layer of the trace level conductors forming terminals for semiconductor device packages;
cutting through the build-up routing layer in scribe lanes between the semiconductor dies to form trenches extending into the semiconductor wafer;
backgrinding the semiconductor wafer on the backside surface of the semiconductor wafer to form openings by exposing the trenches to separate the semiconductor dies from one another; and
covering a portion of the device side surface of the semiconductor dies, a portion of the build-up routing layer, and the openings between the semiconductor dies with mold compound, while the terminals formed of the trace level conductors are exposed from the mold compound.

2. The method of claim 1, and further comprising:
cutting through the mold compound between the semiconductor dies along the trenches to form separated semiconductor device packages.

3. The method of claim 2, and further comprising etching the mold compound to expose sides of the terminals from the mold compound.

4. The method of claim 3, wherein the etching forms non-wettable flanks on the sides of the terminals.

5. The method of claim 3, wherein the etching forms wettable flanks on the sides of the terminals.

6. The method of claim 2, wherein the backside surface of the semiconductor dies is covered with the mold compound.

7. The method of claim 2, wherein a portion of the backside surface of the semiconductor dies is exposed from the mold compound to form a thermal pad.

8. The method of claim 1, wherein depositing the first layer of dielectric material comprises depositing Ajinomoto build-up film (ABF), acrylonitrile butadiene styrene (ABS), acrylonitrile styrene acrylate (ASA), or epoxy resin.

9. The method of claim 1, wherein patterning the connection level conductors further comprises:
depositing a seed layer over the device side surface of the semiconductor dies;
patterning the seed layer using a photoresist and photolithography; and
forming the connection level conductors using electroplating or electroless plating of copper, gold, nickel, palladium, tungsten, tin, silver, or combinations or alloys thereof.

10. The method of claim 2, wherein patterning the connection level conductors comprises:
depositing a seed layer over the device side surface of the semiconductor dies;
patterning the seed layer using photoresist and photolithography to expose the seed layer over the bond pads;
forming the connection level conductors using electroplating or electroless plating of copper or copper alloy; and
stripping the photoresist and removing any unused portions of the seed layer.

11. The method of claim 2, wherein the terminals have a planar surface on a board side surface, the mold compound is formed with a planar surface and is coplanar with the terminals, and the method forms a no-lead semiconductor device package.

12. A semiconductor device package, comprising:
a semiconductor die having bond pads on a device side surface and having an opposing backside surface;
a build-up routing layer on the semiconductor die, comprising:
connection level conductors directly contacting the bond pads and extending from the bond pads to distal ends;
trace level conductors on the connection level conductors, the trace level conductors directly contacting the distal ends of the connection level conductors;
dielectric material surrounding the connection level conductors and the trace level conductors;
terminals formed of portions of a top layer of the trace level conductors having a board side surface exposed from the dielectric material, wherein an electrical connection between the terminals and the bond pads on the device side of the semiconductor die is formed without a solder joint or a bond wire; and
mold compound covering a portion of the semiconductor die, the trace level conductors and the connection level conductors of the build-up routing layer, wherein the board side surface of the terminals is exposed from the mold compound.

13. The semiconductor device package of claim 12, wherein the terminals comprise a first set of terminals configured to carry a high current greater than 1 milliampere, and a second set of terminals, the first set of terminals having a greater area than an area of the second set of terminals.

14. The semiconductor device package of claim 13, wherein the first set of terminals includes terminals configured for coupling to a power supply or a ground potential.

15. The semiconductor device package of claim 13, wherein the first set of terminals includes terminals configured for coupling to a switch node.

16. The semiconductor device package of claim 12, wherein the trace level conductors and the connection level conductors of the build-up routing layer are formed of copper or a copper alloy.

17. The semiconductor device package of claim 12, wherein the trace level conductors and the connection level conductors of the build-up routing layer are formed of copper, gold, palladium, nickel, silver, tin, tungsten, alloys or combinations thereof.

18. The semiconductor device package of claim 12, wherein the dielectric material comprises Ajinomoto build-up film (ABF), acrylonitrile butadiene styrene (ABS), acrylonitrile styrene acrylate (ASA), or epoxy resin.

19. The semiconductor device package of claim 12, wherein the dielectric material is Ajinomoto build-up film (ABF).

20. The semiconductor device package of claim 12, wherein the backside surface of the semiconductor die is exposed from the mold compound and faces away from the board side surface of the semiconductor device package.

21. The semiconductor device package of claim 12, wherein the backside surface of the semiconductor die is covered by the mold compound.

22. The semiconductor device package of claim 12, wherein a board side surface of the semiconductor device package comprises a planar surface, the terminals are coplanar with the planar surface, and the terminals have a board side surface exposed from the dielectric material and the mold compound and are configured for surface mounting.

23. A no-lead semiconductor device package, comprising:
a semiconductor die having bond pads on a device side surface and having an opposing backside surface;
a build-up routing layer over the semiconductor die, comprising:
connection level conductors directly contacting the bond pads and forming post connects extending from the bond pads to distal ends;
trace level conductors on the connection level conductors, the trace level conductors directly contacting the distal ends of the post connects;
dielectric material surrounding the post connects and the trace level connection conductors;
terminals formed of a portion of a top layer of the trace level conductors having a board side surface exposed from the dielectric material, wherein an electrical connection between one of the bond pads of the semiconductor die and one of the terminals is formed without a solder joint or a bond wire; and
mold compound covering the semiconductor die and the build-up routing layer, a board side surface of the terminals exposed from the mold compound, the terminals of the semiconductor device package having a planar surface on the board side surface of the semiconductor device package, wherein the mold compound covering board side surface is planar and is coplanar with the terminals of the semiconductor device package.

24. The no-lead semiconductor device package of claim 23, wherein the backside surface of the semiconductor die is exposed from the mold compound.
